(19) United States
(12) Patent Application Publication
(10) Pub. No.: US 2003/0085767 A1
(43) Pub. Date: May 8, 2003

(54) Resistance-to-digital converter

(76) Inventor: Tomonori Nohara, Hyogo (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 10/167,488

(22) Filed: Jun. 13, 2002

(30) Foreign Application Priority Data
Nov. 5, 2001 (JP) 2001-339842

(51) Int. Cl. H03B 1/00

(52) U.S. Cl. 331/74

(57) ABSTRACT

A resistance-to-digital converter includes a CR oscillator, a time period counter, and an oscillation output counter. The CR oscillator, being connected to a target resistor whose resistance is to be subjected to digital conversion, oscillates at an oscillation time constant including the resistance of the target resistor as a part of the time constant. The time period counter counts a clock signal and defines a predetermined time period. The oscillation output counter counts the oscillation output of the CR oscillator during the predetermined time period, and outputs the count value as the digital value corresponding to the resistance of the target resistor to be converted.

### BACKGROUND OF THE INVENTION

1. Field of the Invention

The present invention relates to a resistance-to-digital converter that is incorporated into a semiconductor integrated circuit, and converts a resistance of a resistor, which is connected between external terminals or between an external terminal and a power supply, into a digital value.

2. Description of Related Art

Recently, TV sets, VTRs, navigation systems and the like have been diversifying their functions. Thus, remote controllers for controlling them must have functions corresponding to the diversification, with satisfying the requirements for size reduction and low power consumption.

Among the remote controllers, there are those with a direction sensing function using a jog shuttle or joystick. For example, some remote controllers used for car navigation systems can control the moving direction of a cursor on the navigation screen by the direction sensing function. More specifically, to sense eight directions, for example, a microcomputer for controlling such a remote controller has eight ports that correspond to the directions to be detected, and are connected to switches disposed in these directions. With the configuration, one of the eight switches is turned on by operating a joystick or the like to establish a connection with one of the ports, thereby enabling the detection of the moving direction.

The configuration that detects only the eight directions has a problem of lacking smoothness because the cursor path becomes stepwise when moving in a slanting direction. One of the methods of eliminating such a problem is to increase the number of ports of the microcomputer and the number of switches. Such a configuration, however, becomes complicated, and disadvantageous in terms of the cost. In view of this, an A/D converter is used conventionally.

FIG. 14 is a block diagram showing a configuration of a direction sensing system using an A/D converter. In this figure, the reference numeral 100 designates an A/D converter for converting an analog input voltage signal supplied via an analog voltage input terminal 101 into a digital signal to be output. The reference numeral 101 designates the analog voltage input terminal that is connected to the A/D converter 100 within a chip for supplying it with the external analog input voltage signal. The reference numeral 102 designates a slider for varying the resistance of a resistor R4 by varying the position of the slider that is linked with a joystick or a jog shuttle. The resistor R4 is formed in an open ring, a first end of which is connected to a power supply A, and a second end of which is connected to a ground B.

Next, the operation of the conventional direction sensing system will be described.

The analog voltage supplied from the power supply A is divided according to the resistance of the resistor R4 determined by the slider 102, and the analog input voltage signal is supplied from the slider 102 to the A/D converter 100 via the analog voltage input terminal 101. A/D converter 100 converts the analog input voltage signal to the digital signal to be output.

Operation of the joy stick or jog shuttle varies the position of the slider 102, and hence the analog input voltage signal supplied to the A/D converter 100. The A/D converter 100 converts the analog input voltage signal varying with the position of the slider 102 into the digital value corresponding to the analog input voltage, and outputs it. Thus, the direction or rotation angle of the joystick or jog shuttle can be detected by the digital value the A/D converter 100 outputs.

When applying the conventional direction sensing system to a car navigation system, the accuracy of the direction sensing is determined by the resolution of the A/D converter 100. For example, an 8-bit A/D converter can discriminate 256 directions. Therefore, the foregoing problem of the stepwise cursor path can be eliminated.

With the foregoing configuration, it is difficult for the conventional direction sensing system to reduce its circuit scale or power consumption.

The problem will be described in more detail.

When the conventional direction sensing system is incorporated into a microcomputer, it usually employs a successive approximation A/D converter with a simple configuration and high accuracy. The successive approximation A/D converter consumes rather large power because its lower limit voltage of operation is rather high at about 2.7-3 V.

Accordingly, to ensure stable operation of the A/D converter in the remote controller worked on a battery with a voltage of about 3 V, various countermeasures must be taken. For example, since the operation voltage of the microcomputer is about 1.8-2.0 V, to incorporate the conventional resistance-to-digital converter into the microcomputer, the microcomputer must include a booster for increasing the voltage to be supplied to the A/D converter to a level higher than the operation voltage of the microcomputer. The addition of the booster increases the circuit scale, and by extension the total area of the chip of the microcomputer.

The successive approximation A/D converter incorporated into the microcomputer is usually fabricated by a CMOS process. Thus, there is a technique of fabricating a low-voltage operation device by selectively dropping the threshold of the transistors in the A/D converter by adding masking or process steps in the fabrication process of the A/D converter. The changes in the process, however, require additional steps, and are disadvantageous in terms of cost.

In addition, the A/D converter has a rather large current consumption of about 0.1-1 mA, as compared with the current consumption of the microcomputer itself of about 1-5 mA. Furthermore, connecting the resistor across the power supply A and the ground B as in the conventional direction sensing system causes a current to flow continuously, thereby reducing the life of the battery of the remote controller.

### SUMMARY OF THE INVENTION

The present invention is implemented to solve the foregoing problems. It is therefore an object of the present invention to provide a resistance-to-digital converter capable of operating at a low voltage, and reducing the chip area and power consumption. The object is implemented without using the conventional A/D converter by converting a resistance itself into a digital value rather than by converting a divided resistance.

According to a first aspect of the present invention, there is provided a resistance-to-digital converter comprising: an oscillator that oscillates at an oscillation frequency corresponding to the resistance of a target resistor; time period counting means for counting a clock signal to determine a predetermined time period; and oscillation output counting means for counting an oscillation output of the oscillator during the predetermined time period, and for outputting its count value as a digital value corresponding to the resistance of the target resistor.

Here, the oscillator may consist of a CR oscillator or a ring oscillator delay circuit.

### BRIEF DESCRIPTION OF THE DRAWINGS

FIG. 1 is a block diagram showing a configuration of an embodiment 1 of the resistance-to-digital converter in accordance with the present invention;

FIG. 2A is a circuit diagram showing a configuration of the CR oscillator 3 in FIG. 1;

FIG. 2B is a waveform chart illustrating the output signal of the CR oscillator 3;

FIG. 3 is a timing chart illustrating the operation of the embodiment 1 of the resistance-to-digital converter;

FIG. 4 is a block diagram showing a configuration of an embodiment 2 of the resistance-to-digital converter in accordance with the present invention;

FIG. 5 is a block diagram showing a configuration of an embodiment 3 of the resistance-to-digital converter in accordance with the present invention;

FIG. 6 is a block diagram showing a configuration of an embodiment 4 of the resistance-to-digital converter in accordance with the present invention;

FIG. 7 is a circuit diagram showing a configuration of the ring oscillator delay circuit of FIG. 6;

FIG. 8 is a block diagram showing a configuration of an embodiment 5 of the resistance-to-digital converter in accordance with the present invention;

FIG. 9 is a block diagram showing another configuration of the embodiment 5 of the resistance-to-digital converter;

FIG. 10 is a block diagram showing a configuration of an embodiment 6 of the resistance-to-digital converter in accordance with the present invention;

FIG. 11 is a block diagram showing a configuration of an embodiment 7 of the resistance-to-digital converter in accordance with the present invention;

FIG. 12 is a block diagram showing a configuration of an embodiment 8 of the resistance-to-digital converter in accordance with the present invention;

FIG. 13 is a block diagram showing a configuration of an embodiment 9 of the resistance-to-digital converter in accordance with the present invention; and

FIG. 14 is a block diagram showing a configuration of a conventional direction sensing system.

### DETAILED DESCRIPTION OF THE PREFERRED EMBODIMENTS

The invention will now be described with reference to the accompanying drawings.

Embodiment 1

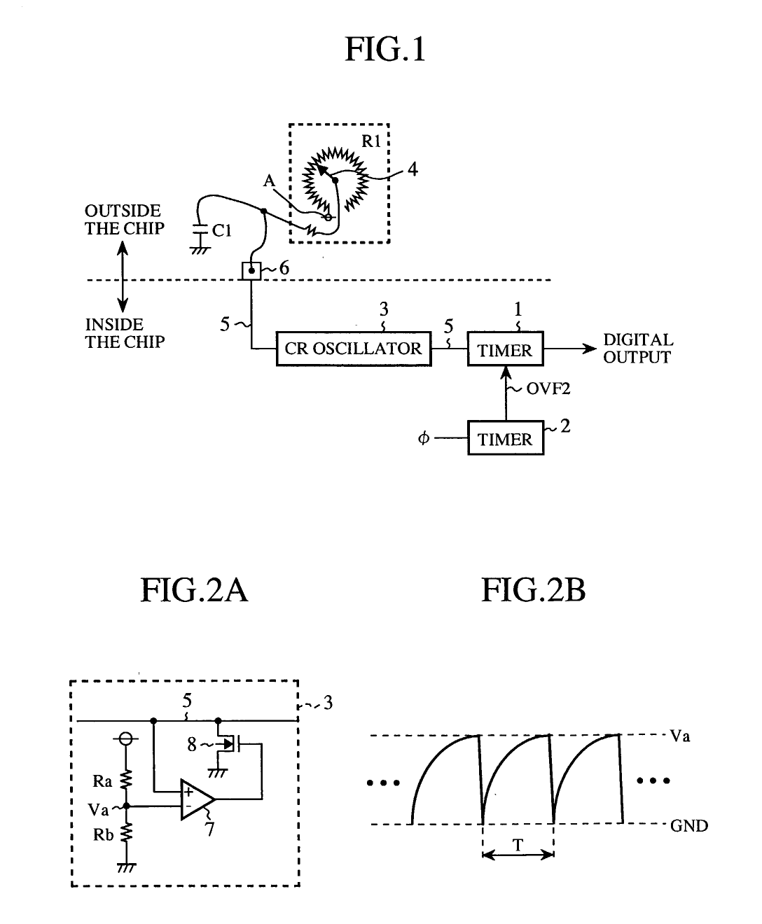

FIG. 1 is a block diagram showing a configuration of an embodiment 1 of the resistance-to-digital converter in accordance with the present invention. The major components of the resistance-to-digital converter are incorporated into a microcomputer chip. In this figure, the reference numeral 1 designates a timer for counting an oscillation output of a CR oscillator 3. It outputs a count value as a digital output. The reference numeral 2 designates a timer for counting pulses of an operating clock signal fed from the microcomputer until it overflows, thereby counting a predetermined time period. The timer 2 employs a count source faster than that of the timer 1. The timers 1 and 2 are implemented using a timer installed in the microcomputer, for example. For the sake of simplicity, the timers 1 and 2 are assumed to be an 8-bit timer in the following description. The reference numeral 3 designates the CR oscillator provided in the microcomputer. It oscillates at a time constant determined by the resistance of a resistor R1 and a capacitance of the capacitor C1. The reference numeral 4 designates a slider of the resistor R1, which determines the value of the resistor R1 according to its position.

The reference numeral 5 designates a signal line for conveying a signal from an external input terminal 6 to the timer 1. The external input terminal 6 is connected to the resistor R1 and capacitor C1 constituting a feedback circuit of the CR oscillator 3, and supplies the microcomputer chip with the signal fed from the outside. Connecting the external input terminal 6 to the resistor R1 and capacitor C1 enables the CR oscillator 3 to oscillate. The reference symbol R1 designates the resistor (target resistor to be converted) with an open ring-like shape, a first end of which is connected to the power supply A, and a second end of which is opened. The resistance-to-digital converter is fabricated in the microcomputer chip through a CMOS process. Since the CR oscillator 3 and timers 1 and 2 can operate at a low voltage, the lower limit voltage of the operation of the resistance-to-digital converter is about 1.8-2.0 V nearly equal to that of the microcomputer.

FIG. 2A is a circuit diagram showing a configuration of the CR oscillator 3 in FIG. 1; and FIG. 2B is a waveform chart illustrating the output signal of the CR oscillator 3. In this figure, the reference numeral 7 designates a comparator for comparing a reference voltage Va with the signal voltage traveling on the signal line 5, and for outputting a digital value indicating the order of their magnitude. The reference numeral 8 designates an N-channel transistor having its gate connected to the output of the comparator 7. The N-channel transistor conducts when the output of the comparator 7 is logic-1, thereby grounding the signal line 5. Reference numerals Ra and Rb designate resistors for generating the reference voltage Va. In FIG. 2A, the same or like components to those of FIG. 1 are designated by the same reference numerals, and the description thereof is omitted here.

Next, the operation of the present embodiment 1 will be described.

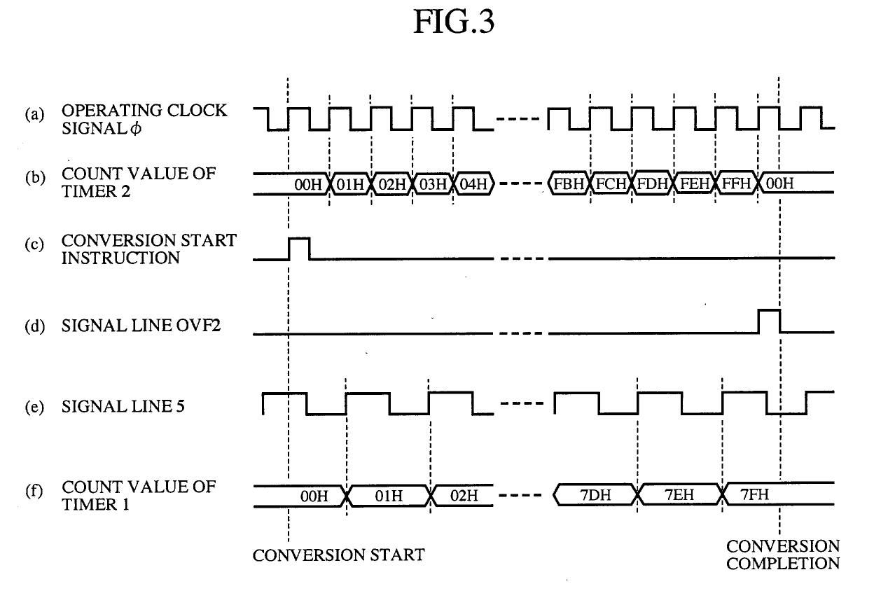

FIG. 3 is a timing chart illustrating the operation of the embodiment 1 of the resistance-to-digital converter, in reference to which the processing of converting the resistance of the resistor R1 to a digital value will be described.

First, receiving a conversion start instruction, which is included in a program executing the digital conversion, from the instruction decoder (not shown) of the microcomputer, the timers 1 and 2 start their counting at the same time. In this case, the timer 1 counts the output clock signal fed from the CR oscillator 3 via the signal line 5 at each period as illustrated in FIG. 3(f).

On the other hand, the timer 2 counts the operating clock signal φ of the microcomputer at each period of the operating clock signal φ as illustrated in FIG. 3(b). In the course of this, when the timer 2 counts from 00H to FFH, that is, when it overflows, the timer 2 supplies the timer 1 with the signal OVF2 indicating the overflow, thereby stopping both the timers 1 and 2.

The timer 1 outputs its count value by counting the clock signal from the CR oscillator 3 during the fixed time period the timer 2 determines by counting the operating clock signal φ from 00H to FFH, as a digital conversion value of the resistance of the resistor R1 determined by the position of the slider 4. In the example of FIG. 3, the count value 7FH of the timer 1 is the conversion result.

The CR oscillator 3 will now be described in more detail. As shown in FIG. 2A, the signal line 5, which is connected to the resistor R1 and capacitor C1 via the external input terminal 6, is connected to the non-inverting input terminal of the comparator 7, and to the source of the N-channel transistor 8. The reference voltage Va is designed to be 63% of the voltage of the power supply A. This is because when the power supply A charges the capacitor C1 through the resistor R1, the time T at which the potential of the signal line 5 becomes 63% of the power supply voltage is expressed by the following equation (1)

T=C1·R1 (1)

where C1 is the capacitance of the capacitor C1, and R1 is the resistance of the resistor R1 determined by the position of the slider 4.

The operation of the CR oscillator 3 will be described briefly because it is a known matter. As illustrated in FIG. 2B, the signal line 5 is charged by the CR integrator outside the microcomputer chip from the ground level GND to the potential Va during the oscillation period T given by the foregoing equation (1). Thus, when the potential of the non-inverting input of the comparator 7 exceeds that of the inverting input, the gate of the N-channel transistor 8 is changed from the low level to the high level. The N-channel transistor 8 closes or opens the connection between the signal line 5 and ground GND in response to the digital value supplied to its gate. Thus, the CR oscillator 3 oscillates at the oscillation period T=C1·R1. Therefore, when the capacitance of the capacitor C1 is fixed, the oscillation period is proportional to the resistance of the resistor R1.

In this way, the timer 1 counts, during the fixed time period, the oscillation output of the CR oscillator 3, the oscillation period of which is proportional to the resistance of the resistor R1. Accordingly, the count value of the timer 1, which is the digital output, is proportional to the resistance of the resistor R1.

As described above, the present embodiment 1 employs the CR oscillator 3 and timers 1 and 2 capable of operating at a voltage lower than the operating voltage of the conventional converter using the A/D converter. Therefore, it can achieve the lower limit voltage of operation of the microcomputer, thereby reducing the chip size and power consumption. In addition, since the present embodiment 1 does not convert the voltage divided by the resistors as the conventional converter, it can prevent the current flowing from the power supply to the ground via the resistor, thereby reducing the current consumption.

In addition, utilizing the timer installed in the microcomputer as the timers 1 and 2 can increase the area efficiency in the chip.

Although the timers 1 and 2 are each assumed to be an 8-bit timer in the present embodiment 1, timers with any number of bits are applicable. In addition, although the capacitor C1 is connected in the outside of the microcomputer chip, it can be placed in the chip.

Embodiment 2

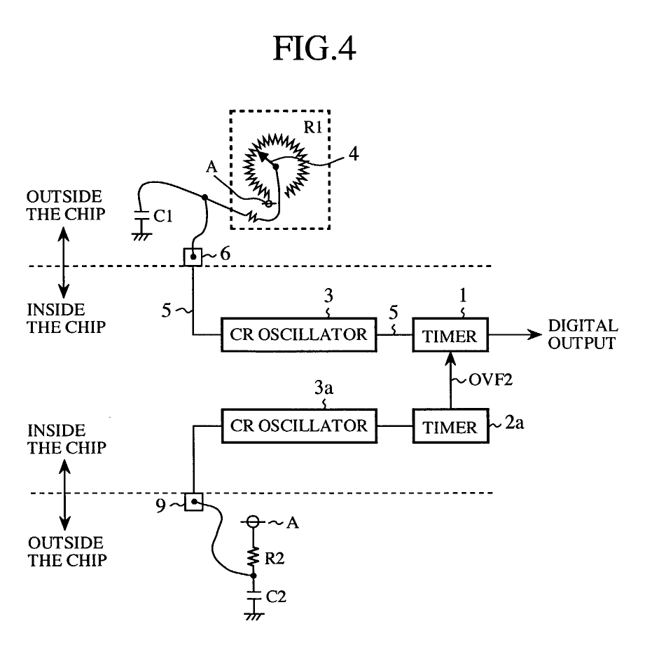

FIG. 4 is a block diagram showing a configuration of an embodiment 2 of the resistance-to-digital converter in accordance with the present invention. In this figure, the reference numeral 2a designates a timer for counting the oscillation output of a CR oscillator 3a until it overflows, thereby counting a predetermined time period. The timer 2a uses a count source faster than that of the timer 1. The reference numeral 3a designates the CR oscillator with a configuration similar to that of the CR oscillator 3 as shown in FIG. 2A, which oscillates using a feedback circuit consisting of a resistor R2 and a capacitor C2 connected via an external input terminal 9. The same or like components to those of FIG. 1 are designated by the same reference numerals and the description thereof is omitted here.

Next, the operation of the present embodiment 2 will be described.

First, receiving a conversion start instruction, which is included in a program executing the digital conversion, from the instruction decoder (not shown) in the microcomputer, the timers 1 and 2a start their counting at the same time. In this case, the timer 1 counts the clock signal fed from the CR oscillator 3 via the signal line 5. On the other hand, the timer 2a counts the oscillation output of the CR oscillator 3a. In the course of this, when the timer 2a overflows, it supplies the timer 1 with the signal OVF2 indicating the overflow, thereby stopping both the timers 1 and 2a.

Thus, the timer 1 counts the output clock signal of the CR oscillator 3 during the fixed time period the timer 2a determines by counting the oscillation output of the CR oscillator 3a. Then, the count value of the timer 1 is output as the digital conversion value corresponding to the resistance of the resistor R1 determined by the position of the slider 4.

As described above, the present embodiment 2 is configured such that the timer 2a counts as the reference clock signal the oscillation output of the CR oscillator 3a with the same circuit configuration as the CR oscillator 3 instead of counting the operating clock signal φ of the microcomputer. As a result, the present embodiment 2 can compensate for the frequency drift of the CR oscillator 3 due to ambient temperature or power supply voltage, thereby improving the conversion accuracy.

The present embodiment 2 can control the resolution or conversion speed of the resistance-to-digital converter by varying the resistance of the resistor R2 or the capacitance of the capacitor C2 connected to the external input terminal 9. In addition, the capacitors C1 and C2 may be incorporated into the chip.

Embodiment 3

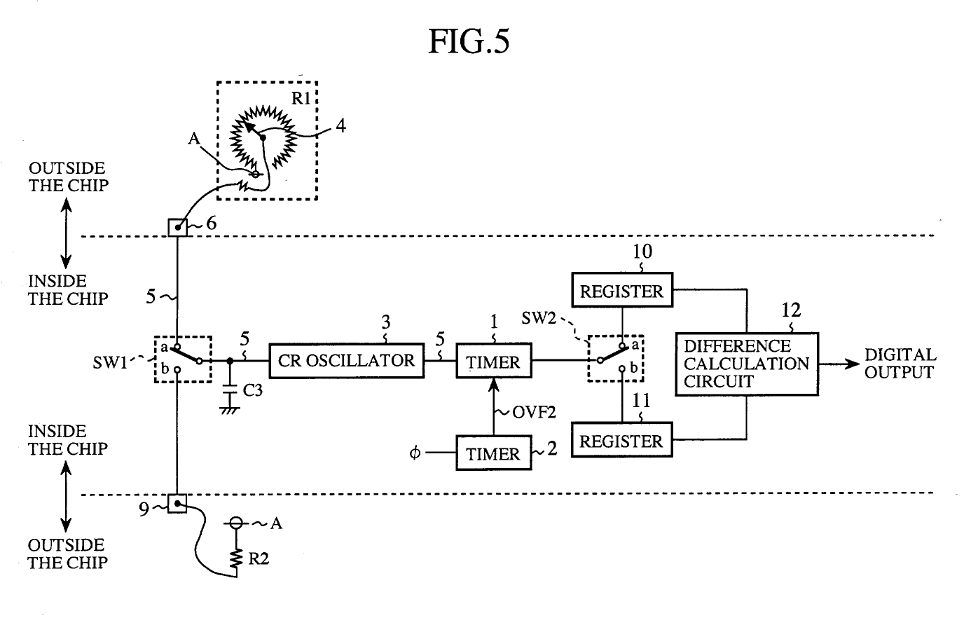

FIG. 5 is a block diagram showing a configuration of an embodiment 3 of the resistance-to-digital converter in accordance with the present invention. In this figure, reference numerals 10 and 11 each designates a register for storing the count value of the timer 1. The register 10 stores the count value the timer 1 outputs by counting the oscillation output of the CR oscillator 3 using the feedback circuit consisting of the resistor R1 and a capacitor C3. On the other hand, the register 1a stores the count value the timer 1 outputs by counting the oscillation output of the CR oscillator 3 using the feedback circuit consisting of the resistor R2 and the capacitor C3. Here, the resistor R1 is the target resistor whose resistance is determined by the slider 4, and to be subjected to the digital conversion as in the foregoing embodiment 1. In contrast, the resistor R2 is a reference resistor whose resistance is known in advance. In other words, the oscillation frequency of the CR oscillator 3 with the feedback circuit consisting of the resistor R2 and capacitor C3 is known. The reference numeral 12 designates a difference calculation circuit for computing the difference between the count values stored in the registers 10 and 11. The reference symbol SW1 designates a switch for switching the connection of the input of the CR oscillator 3; and SW2 designates a switch for switching the register for storing the count value of the timer 1 between the register 10 and register 11. The same or like components to those of FIG. 1 are designated by the same reference numerals and the description thereof is omitted here.

Next, the operation of the present embodiment 3 will be described.

First, receiving a conversion start instruction, which is included in the program executing the digital conversion, from the instruction decoder (not shown) of the microcomputer, the timers 1 and 2 start their counting at the same time as in the foregoing embodiment 1. The program executing the digital conversion includes instructions for placing the switches SW1 and SW2 at the position a or position b. Before sending the conversion start instruction to the timers 1 and 2, the switches SW1 and SW2 are set at the position a of FIG. 5. Thus, the CR oscillator 3 oscillates using the feedback circuit consisting of the resistor R1 and capacitor C3 connected via the signal line 5. Accordingly, the timer 1 counts the clock signal supplied from the CR oscillator 3 via the signal line 5.

On the other hand, the timer 2 counts the operating clock signal φ of the microcomputer until it overflows as in the foregoing embodiment 1. When the timer 2 overflows, it supplies the timer 1 with the signal OVF2. Receiving the overflow signal OVF2, the timer 1 stores the count value of the output of the CR oscillator 3 at the time when the timer 2 overflows into the register 10 connected to the position a of the switch SW2, wherein the CR oscillator 3 oscillates using the feedback circuit consisting of the resistor R1 and capacitor C3. After completing the storing of the count value, both the timers 1 and 2 are initialized.

Subsequently, the microcomputer executing the program places the switches SW1 and SW2 at the position b, and supplies the conversion start instruction to the timers 1 and 2, again. Thus, the timers 1 and 2 start their counting simultaneously. In this case, the CR oscillator 3 oscillates using the feedback circuit consisting of the resistor R2 and capacitor C3 connected via the signal line 5. Then, the timer 1 counts the output clock signal of the CR oscillator 3 supplied via the signal line 5.

Subsequently, the timer 2 counts the operating clock signal φ of the microcomputer until it overflows as described above. When the timer 2 overflows, it supplies the timer 1 with the signal OVF2. Receiving the overflow signal OVF2, the timer 1 stores the count value of the output of the CR oscillator 3 at the time when the timer 2 overflows into the register 11 connected to the position b of the switch SW2, wherein the CR oscillator oscillates using the feedback circuit consisting of the resistor R2 and capacitor C3.

In this way, the count value corresponding to the resistor R1 and the count value corresponding to the resistor R2 are stored into the registers 10 and 11, respectively. Subsequently, the difference calculation circuit 12 reads the count values the registers 10 and 11 store, calculates the difference between them, and outputs it. The difference is simply proportional to the difference between the resistors R1 and R2. Since the resistor R2 has a known fixed value, the difference is considered to be a digital value corresponding to the target resistor R1 to be converted.

As described above, the present embodiment 3 is configured such that the CR oscillator 3 oscillates using the target resistor R1 to be subjected to the digital conversion or the reference resistor R2, and that the difference between the count values corresponding to the target resistor R1 and the reference resistor R2 is output as the digital value corresponding to the target resistor R1. Accordingly, the present embodiment 3 can compensate for the frequency drift of the CR oscillator 3 due to the ambient temperature or power supply voltage, thereby improving the conversion accuracy.

Furthermore, the present embodiment 3 can use all the components except for the resistors R1 and R2 in common between the target resistor R1 side and the reference resistor R2 side. As a result, the present embodiment 3 can reduce the variations in the fabrication process of the internal circuit as compared with the foregoing embodiment 2.

Embodiment 4

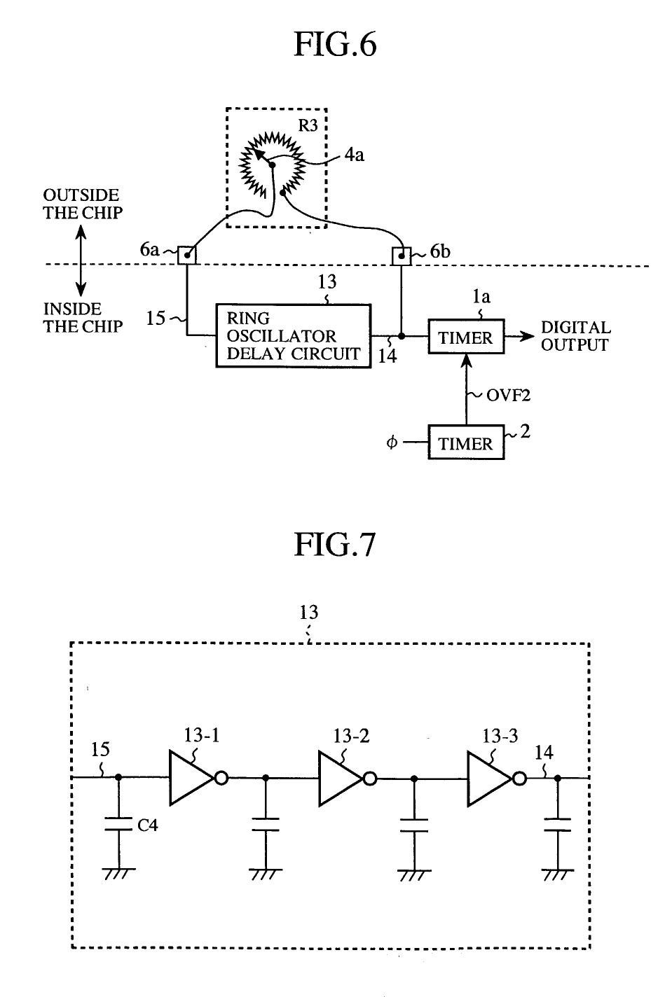

FIG. 6 is a block diagram showing a configuration of an embodiment 4 of the resistance-to-digital converter in accordance with the present invention. In this figure, the reference numeral 1a designates a timer for counting the oscillation output of a ring oscillator delay circuit 13, and for outputting the count value as a digital output. As in the foregoing embodiments, the timer 2 uses a count source faster than that of the timer 1. The reference numeral 4a designates a slider of a resistor R3. The slider 4a, which determines the resistance of the resistor R3, is connected to the input of the ring oscillator delay circuit 13 via the external input terminal 6a and signal line 15. The reference numerals 6a and 6b each designate an external input-terminal of the microcomputer chip including the resistance-to-digital converter. These input terminals 6a and 6b are connected to the end of the slider 4a and the end of the resistor R3 outside the chip, and to the signal lines 15 and 14 inside the chip. Thus, the ring oscillator delay circuit 13 is connected in a ring fashion via the target resistor R3 whose resistance is to be subjected to the digital conversion, and the signal lines 14 and 15.

The ring oscillator delay circuit 13 oscillates at an oscillation period including as its integral part the delay corresponding to the resistance of the resistor R3 determined by the position of the slider 4a. The signal line 14 connects the output of the ring oscillator delay circuit 13 to the timer 1a and external input terminal 6b, and the signal line 15 connects the external input terminal 6a to the input of the ring oscillator delay circuit 13. The open ring-like resistor R3 has its one end connected to the output of the ring oscillator delay circuit 13 via the external input terminal 6b and signal line 14, with the other end being opened. The resistance-to-digital converter is formed in the microcomputer chip by a CMOS process. Since the ring oscillator delay circuit 13 and the timers 1a and 2 can operate at a low voltage, the lower limit voltage of the operation of the resistance-to-digital converter is about 1.8 -2.0 V which is nearly the same as that of the microcomputer. Incidentally, in FIG. 6, the same or like components to those of FIG. 1 are designated by the same reference numerals, and the description thereof is omitted here.

FIG. 7 is a circuit diagram showing a configuration of the ring oscillator delay circuit 13 of FIG. 6. In this figure, reference numerals 13-1-13-3 each designate an inverter constituting the ring oscillator delay circuit 13. These inverters are connected in series, and respective connecting sections are each connected to the ground GND via a capacitor C4. Thus, the ring oscillator delay circuit 13 oscillates at the oscillation period including as its integral part the delay corresponding to the resistance of the resistor R3.

Next, the operation of the present embodiment 4 will be described.

First, receiving a conversion start instruction, which is included in a program executing the digital conversion, from the instruction decoder (not shown) in the microcomputer, the timers 1a and 2 start their counting at the same time. In this case, the timer 1a counts the output clock signal fed from the ring oscillator delay circuit 13 via the signal line 14. On the other hand, the timer 2 counts the operating clock signal φ of the microcomputer.

In the course of this, when the timer 2 overflows, it supplies the timer 1a with the signal OVF2 indicating the overflow, thereby stopping both the timers 1a and 2.

Thus, the timer 1a counts the output clock signal of the ring oscillator delay circuit 13 during the fixed time period determined by the overflow of the timer 2. Then, the timer 1a outputs its count value as the digital conversion value corresponding to the resistance of the resistor R3, which is determined by the position of the slider 4a.

The ring oscillator delay circuit 13 has the oscillation period of 2T, where T is its delay (oscillation frequency f is ½T). When a ring-like connection is formed as shown in FIG. 6 by connecting the signal line 15, ring oscillator delay circuit 13, and signal line 14 via the resistor R3, a delay caused by the resistor R3 and the capacitors C4 of FIG. 7 is added to the delay 2T of the ring oscillator delay circuit 13 itself when the resistor R3 is not interposed. Since the additional delay is proportional to the resistor R3, the digital value corresponding to the resistance of the resistor R3 can be obtained in the same manner as the foregoing embodiment 1.

As described above, the present embodiment 4 is configured by using the ring oscillator delay circuit 13 and timers 1a and 2 capable of operating at a low voltage rather than by using the A/D converter as the conventional converter. Therefore, it can operate at nearly the same lower limit voltage of operation as that of the microcomputer, thereby enabling the reduction in the chip size and power consumption. In addition, since the present embodiment 4 outputs, as the digital value corresponding to the resistance of the resistor R3, the count value of the oscillation output of the ring oscillator delay circuit 13, the oscillation period of which includes as its integral part the delay proportional to the resistor R3, rather than converting the voltage divided by the resistors as the conventional converter, it can prevent the current flowing from the power supply to the ground via the resistor, thereby reducing the current consumption.

In addition, utilizing the timer that is normally installed in the microcomputer as the timers 1a and 2 can improve the area efficiency in the chip as the foregoing embodiment 1.

Embodiment 5

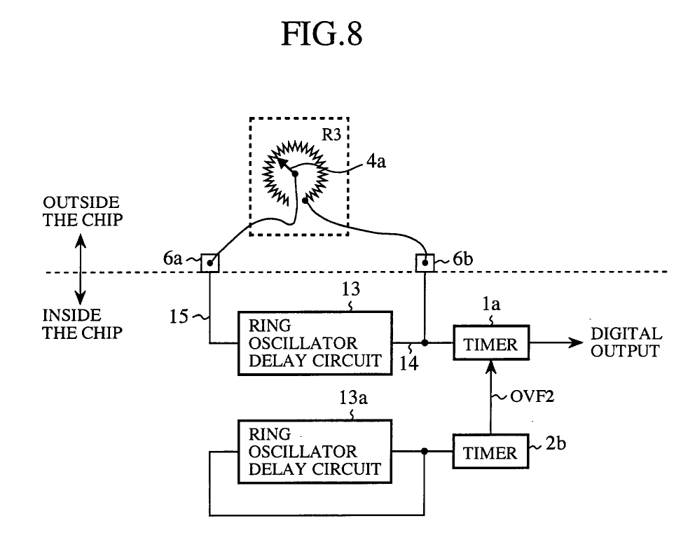

FIG. 8 is a block diagram showing a configuration of an embodiment 5 of the resistance-to-digital converter in accordance with the present invention. In this figure, the reference numeral 2b designates a timer for counting the oscillation output of a ring oscillator delay circuit 13a until it overflows, thereby defining a predetermined time period. The timer 2b uses a count source faster than that of the timer 1a. The ring oscillator delay circuit 13a has a configuration similar to that of the ring oscillator delay circuit 13 as shown in FIG. 6, and oscillates with its input and output terminals being short-circuited without the resistor. Incidentally, in FIG. 8, the same or like components to those of FIG. 6 are designated by the same reference numerals, and the description thereof is omitted here.

Next, the operation of the present embodiment 5 will be described.

First, receiving a conversion start instruction, which is included in a program executing the digital conversion, from the instruction decoder (not shown) in the microcomputer, the timers 1a and 2b start their counting at the same time. In this case, the timer 1a counts the output clock signal fed from the ring oscillator delay circuit 13 via the signal line 14. On the other hand, the timer 2b counts the oscillation output of the ring oscillator delay circuit 13a. In the course of this, when the timer 2b overflows, it supplies the timer 1a with the signal OVF2 indicating the overflow, thereby stopping both the timers 1a and 2b.

Thus, the timer 1a counts the output clock signal of the ring oscillator delay circuit 13 during the fixed time period the timer 2b determines by counting the oscillation output of the ring oscillator delay circuit 13a. Then, the count value of the timer 1a is output as the digital conversion value corresponding to the resistance of the resistor R3 determined by the position of the slider 4a.

As described above, the present embodiment 5 is configured such that the timer 2b counts as the reference clock signal the oscillation output of the ring oscillator delay circuit 13a with the same circuit configuration as the ring oscillator delay circuit 13 instead of counting the operating clock signal φ of the microcomputer. As a result, the present embodiment 5 can compensate for the frequency drift of the ring oscillator delay circuit 13 due to ambient temperature or power supply voltage, thereby improving the conversion accuracy.

Although the loop including the ring oscillator delay circuit 13a does not include a resistor in the present embodiment 5, the loop can include a resistor for adjusting the reference frequency of the ring oscillator delay circuit 13a.

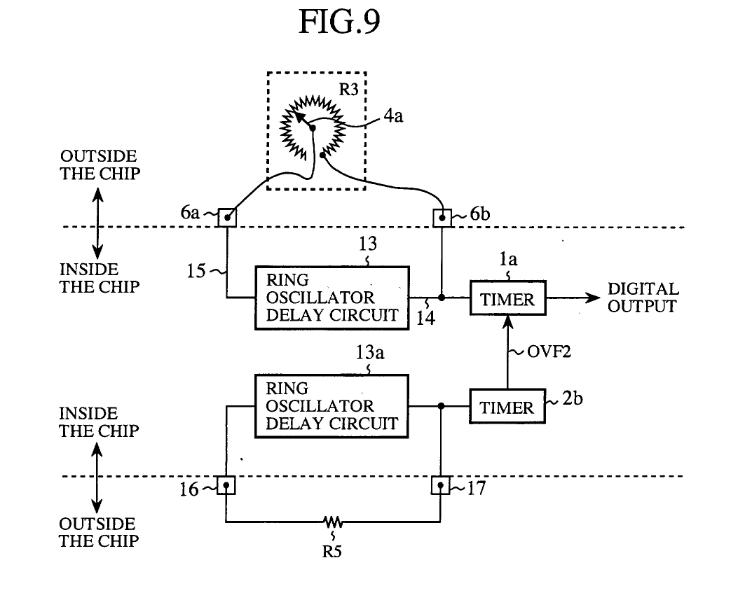

FIG. 9 is a block diagram showing such a configuration of the embodiment 5 of the resistance-to-digital converter. In this figure, the reference symbol R5 designates a resistor for adjusting the reference frequency of the ring oscillator delay circuit 13a. The resistance of the resistor R5 is controllable at the outside of the chip. Reference numerals 16 and 17 designate resistor terminals provided on the chip to connect the resistor R5 between the input and output of the ring oscillator delay circuit 13a. In FIG. 9, the same or like components to those of FIG. 8 are designated by the same reference numerals, and the description thereof is omitted here.

The resistor terminals 16 and 17 as shown in FIG. 9 enable the resistor R5 to be replaced with a resistor of a desired resistance, thereby making it possible to adjust the reference frequency of the ring oscillator delay circuit 13a. Accordingly, the configuration can adjust the resolution or conversion speed of the resistance-to-digital converter. In addition, the resistor R5 can be replaced by a variable resistor with achieving the same advantages as described above.

Embodiment 6

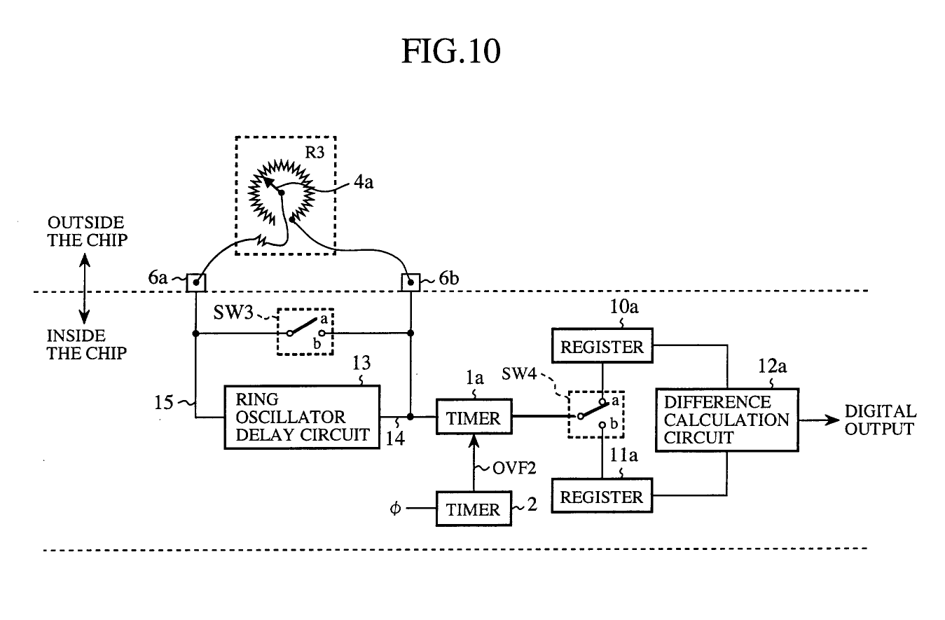

FIG. 10 is a block diagram showing a configuration of an embodiment 6 of the resistance-to-digital converter in accordance with the present invention. In this figure, reference numerals 10a and 11a each designate a register for storing the count value of the timer 1. The register 10a stores the count value the timer 1 outputs by counting the oscillation output of the ring oscillator delay circuit 13 that oscillates at the oscillation period including as its integral part the delay corresponding to the resistor R3. On the other hand, the register 11a stores the count value the timer 1 outputs by counting the oscillation output of the ring oscillator delay circuit 13 that oscillates at the oscillation period when the signal lines 14 and 15 are short-circuited without interposing the resistor R3. Here, the oscillation frequency of the ring oscillator delay circuit 13 when the signal lines 14 and 15 are short-circuited without interposing the resistor R3 is known. The reference numeral 12a designates a difference calculation circuit for computing the difference between the count values stored in the registers 10a and 11a. The reference symbol SW3 designates a switch for switching the connection between the input and output of the ring oscillator delay circuit 13. The switch SW3 forms a path connecting the input and output of the ring oscillator delay circuit 13 via the resistor R3 when the switch SW3 is open at the position a, and a path short-circuiting the input and output of the ring oscillator delay circuit 13 when the switch SW3 is closed at the position b. The reference symbol SW4 designates a switch for switching the register for storing the count value of the timer 1a between the register 10a and register 11a. The same or like components to those of FIG. 6 are designated by the same reference numerals and the description thereof is omitted here.

Next, the operation of the present embodiment 6 will be described.

First, receiving a conversion start instruction, which is included in a program executing the digital conversion, from the instruction decoder (not shown) of the microcomputer, the timers 1a and 2 start their counting at the same time as in the foregoing embodiment 1. The program executing the digital conversion includes instructions for placing the switches SW3 and SW4 at the position a or b. Before sending the conversion start instruction to the timers 1a and 2, the switches SW3 and SW4 are set at the position a of FIG. 10. Thus, the ring oscillator delay circuit 13 oscillates using the loop consisting of the signal lines 14 and 15 and the target resistor R3 with the resistance to be subjected to the digital conversion. Then, the timer 1a counts the clock signal supplied from the ring oscillator delay circuit 13 via the signal line 14.

On the other hand, the timer 2 counts the operating clock signal φ of the microcomputer until it overflows as in the foregoing embodiment 1. When the timer 2 overflows, it supplies the timer 1a with the signal OVF2. Receiving the overflow signal OVF2, the timer 1a stores the count value of the output of the ring oscillator delay circuit 13 into the register 10a that is connected to the position a of the switch SW4 at the time when the timer 2 overflows, wherein the ring oscillator delay circuit 13 oscillates using the loop including the resistor R3. After completing the storing of the count value, both the timers 1a and 2 are initialized.

Subsequently, the microcomputer executing the program places the switches SW3 and SW4 at the position b, and supplies the conversion start instruction to the timers 1a and 2, again. Thus, the timers 1a and 2 start their counting simultaneously. In this case, the ring oscillator delay circuit 13 oscillates with the signal lines 14 and 15 short-circuited without interposing the resistor R3. Then, the timer 1a counts the output clock signal of the ring oscillator delay circuit 13 supplied via the signal line 14.

In parallel with this, the timer 2 counts the operating clock signal φ of the microcomputer until it overflows as in the foregoing. When the timer 2 overflows, it supplies the timer 1a with the signal OVF2. Receiving the overflow signal OVF2, the timer 1a stores the count value of the output of the ring oscillator delay circuit 13 into the register 11a connected to the position b of the switch SW4 at the time when the timer 2 overflows.

In this way, the count value corresponding to the resistor R3 and the count value corresponding to the short-circuit are stored into the registers 10a and 11a, respectively. Subsequently, the difference calculation circuit 12a reads the count values the registers 10a and 11a store, calculates the difference between them, and outputs it. The difference is simply proportional to the resistance of the resistor R3. Since the count-value at the short-circuit is a known fixed value, the difference is considered to be a digital value corresponding to the target resistor R3 to be converted.

As described above, the present embodiment 6 is configured such that the ring oscillator delay circuit 13 oscillates with either the resistor R3 interposed or short-circuited, and that the difference between the count value corresponding to the target resistor R3 to be subjected to the digital conversion and the count value corresponding to the short-circuit is output as the digital value corresponding to the resistor R3. Accordingly, the present embodiment 6 can compensate for the frequency drift of the ring oscillator delay circuit 13 due to the ambient temperature or power supply voltage, thereby improving the conversion accuracy.

Furthermore, the present embodiment 6 can use all the components except for the resistor R3 in common between the target resistor R3 side to be subjected to the digital conversion-and the short-circuit side. As a result, the present embodiment 6 can reduce the variations in the fabrication process of the internal circuit as compared with the foregoing embodiment 5.

Embodiment 7

The present embodiment 7 adds to the foregoing embodiments 1-6 a circuit for setting a desired value to the timer 1 or 1a.

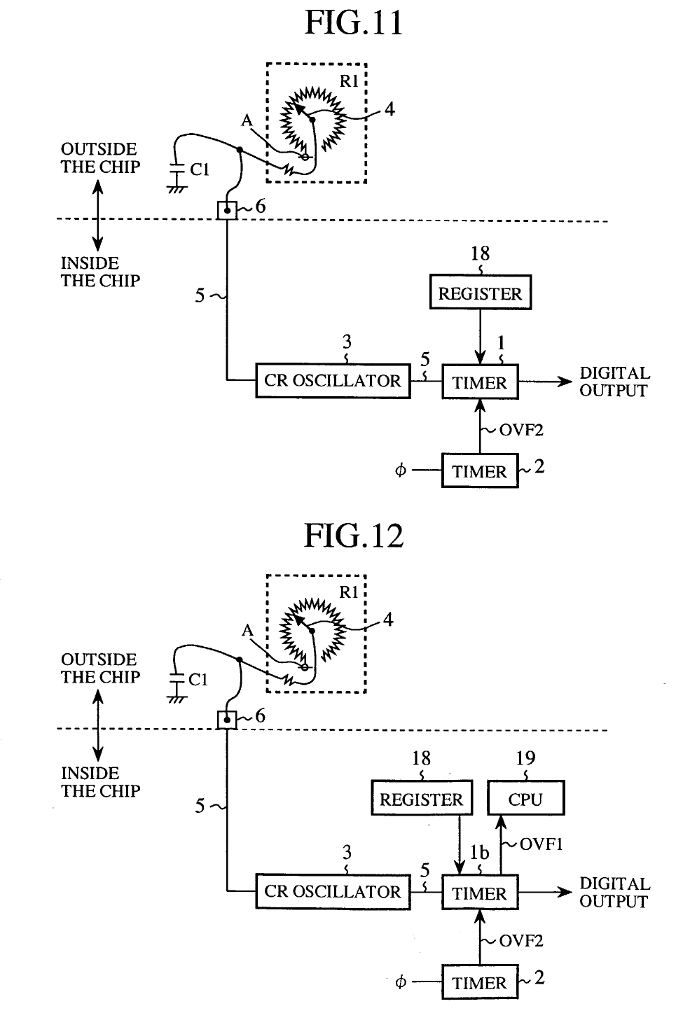

FIG. 11 is a block diagram showing a configuration of an embodiment 7 of the resistance-to-digital converter in accordance with the present invention. The example adds to the configuration as shown in FIG. 1 a setting circuit for setting a desired value to the timer 1. In this figure, the reference numeral 18 designates register for storing a value to be written into the timer 1. In FIG. 11, the same or like components to those of FIG. 1 are designated by the same reference numerals, and the description thereof is omitted here.

Next, the operation of the present embodiment 7 will be described.

The basic operation is the same as that of the foregoing embodiment 1, except that the present embodiment 7 places the value stored in the register 18 into the timer 1 as its initial value at the start of the conversion. Thus, placing a desired value into the register 18 enables desired offset correction. For example, the timer 1 usually starts its count from 00H as illustrated in the timing chart of FIG. 3. However, if the register 18 is set at 11H, the conversion result will become 90H, for example, thereby providing the offset correction.

As described above, since the present embodiment 7 comprises the circuit for setting a desired value to the timer 1 or 1a, it can carry out the desired offset correction. Accordingly, applying the resistance-to-digital converter to the direction sensing system makes it possible to adjust the sensing direction without changing the resistance of the external resistor, or the capacitance of the capacitor. For example, to rotate the sensing direction by 90 degrees with respect to the direction of the joystick, the software of the microcomputer can properly handle it.

Embodiment 8

The present embodiment 8 comprises, in addition to the foregoing embodiments 1-7, a circuit for checking whether the timer 1 or 1a overflows when counting the oscillation output.

FIG. 12 is a block diagram showing a configuration of an embodiment 8 of the resistance-to-digital converter in accordance with the present invention. The present embodiment 8 comprises a circuit for checking whether the overflow occurs or not in addition to the configuration as shown in FIG. 11. In FIG. 12, the reference numeral 1b designates a timer for counting the oscillation output of the CR oscillator 3. The timer 1b not only operates as in the foregoing embodiment 1, but also supplies, when it overflows, a CPU 19 with an overflow signal OVF1 indicating the overflow. Receiving the overflow signal OVF1 from the timer 1b, the CPU 19 of the microcomputer that includes the embodiment 8 of the resistance-to-digital converter, checks whether the timer 1b overflows or not. In FIG. 12, the same or like components to those of FIG. 11 are designated by the same reference numerals, and the description thereof is omitted here.

Next, the operation of the present embodiment 8 will be described.

The basic operation is the same as that of the foregoing embodiment 7, except that in the present embodiment 8, if the timer 1b overflows during the digital conversion of the resistance, it supplies the overflow signal OVF1 to the CPU 19 each time the overflow occurs. Every time receiving the overflow signal OVF1, the CPU 19 records the overflow of the timer 1b in a memory not shown, for example.

At the end of the digital conversion, the CPU 19 can process the digital output value of the timer 1b in accordance with the recorded data. Specifically, since the CPU 19 can check the history of the overflow of the timer 1b from the recorded data, it can use the count value that exceeds the maximum value of the timer 1b as the digital value corresponding to the resistance.

The foregoing embodiments 1-7 assume that the count source of the timer 2 (or 2a or 2b) is faster than that of the time 1 (or 1a) so that the timer 1 (or 1a) does not overflow by adjusting the resistor or capacitor. In other words, the interval during which the timer 1 or 1a counts the oscillation output is determined by the number of digits of the timer 2 (or 2a or 2b) that counts the interval.

On the other hand, in the present embodiment 8, the CPU 19 can decide as to whether the timer 1b overflows or not, and the number of times it overflows, and can handle the digital output of the timer 1b in response to the decision as to the timer 1b. For example, before the overflow of the timer 1b, the CPU 19 can utilize the count value of the timer 1b as it is as the digital output. Even after the overflow, the count value is obtained correctly by adding the maximum count value of the timer 1b in accordance with the history of the overflow.

As described above, the present embodiment 8 is configured such that the CPU 19 can check the presence or absence of the overflow of the timer 1b, and the number of times of the overflows. Thus, the CPU 19 can decide as to whether the digital output value of the timer 1b is the value before or after the overflow, and the number of times of the overflows, after completing the conversion. As a result, the present embodiment 8 can improve the resolution substantially.

Embodiment 9

The present embodiment 9 comprises a circuit for setting a desired value into the timer 2 (or 2a or 2b) in addition to the foregoing embodiments 1-8.

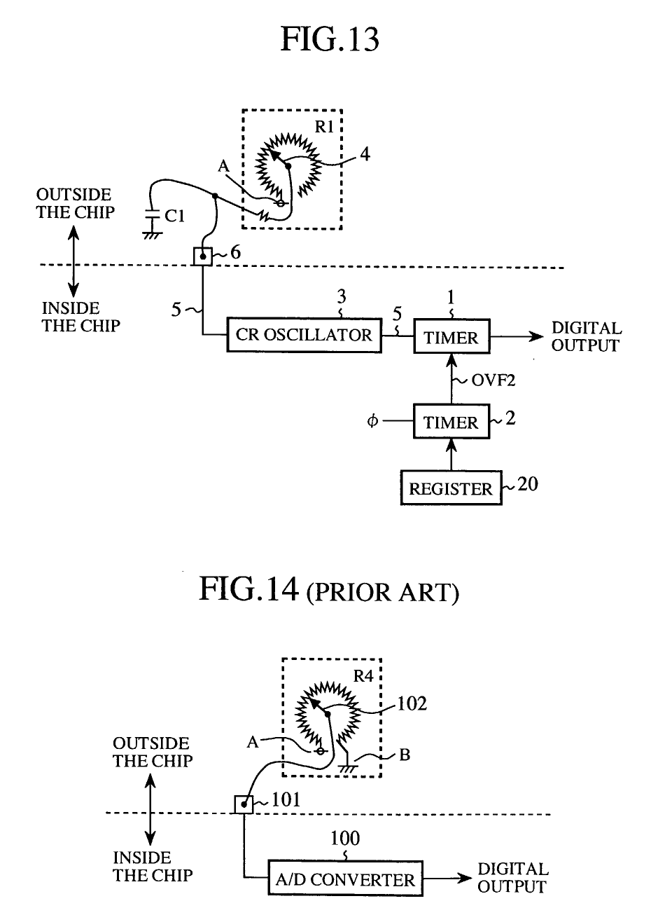

FIG. 13 is a block diagram showing a configuration of an embodiment 9 of the resistance-to-digital converter in accordance with the present invention. The present embodiment 9 adds to the configuration as shown in FIG. 1 a circuit for setting a desired value to the timer 2. In FIG. 13, the reference numeral 20 designates a register for storing a value to be placed into the timer 2. In FIG. 13, the same or like components to those of FIG. 1 are designated by the same reference numerals, and the description thereof is omitted here.

Next, the operation of the present embodiment 9 will be described.

Although the basic operation is the same as that of the foregoing embodiment 1, the present embodiment 9 places the value stored in the register 20 into the timer 2 as the initial value for the conversion. In other words, setting a desired value in the register 20 enables the conversion at desired resolution and conversion speed. For example, although the timer 2 starts its count from 00H in the timing chart of FIG. 3, by placing FCH into the register 20 in the present embodiment 9, for example, the conversion result becomes 02H. Thus, although the resolution becomes rougher, the conversion speed becomes faster.

As described above, since the present embodiment 9 comprises the circuit for setting a desired value to the timer 2 (or 2a or 2b), it can perform the conversion at desired resolution and conversion speed. Therefore, applying the resistance-to-digital converter to the direction sensing system makes it possible to carry out the finer adjustment of the sensing direction without changing the resistance of the external resistor and the capacitance of the capacitor.

It is also possible for the foregoing embodiments to comprise an oscillation controller for controlling the CR oscillator or ring oscillator delay circuit such that they oscillate only during the digital conversion. For example, the program for executing the digital conversion can have a function to output an instruction to start or stop the oscillation of the CR oscillator or ring oscillator delay circuit in conjunction with the digital conversion. In this way, the CPU of the microcomputer can implement the oscillation controller. By thus controlling the oscillator so that it oscillates only during the digital conversion, the power consumption can be reduced further.

What is claimed is:

1. A resistance-to-digital converter comprising:
an oscillator that is connected to a target resistor whose resistance is to be subjected to digital conversion, and that oscillates at an oscillation frequency corresponding to the resistance of the target resistor;
time period counting means for counting a clock signal to determine a predetermined time period; and
oscillation output counting means for counting an oscillation output of said oscillator during the predetermined time period, and for outputting its count value as a digital value corresponding to the resistance of the target resistor.

2. The resistance-to-digital converter according to claim 1, wherein said oscillator consists of a CR oscillator.

3. The resistance-to-digital converter according to claim 2, wherein said CR oscillator is selectively connected to one of the target resistor to be converted and a reference resistor, and oscillates at the oscillation frequency corresponding to the resistance of the connected resistor, said resistance-to-digital converter further comprising:
target data storing means for storing the count value of said oscillation output counting means corresponding to the target resistor to be converted; and
reference data storing means for storing the count value of said oscillation output counting means corresponding to the reference resistor.

4. The resistance-to-digital converter according to claim 2, further comprising difference output means for calculating a difference between the count value stored in said target data storing means and the count value stored in said reference data storing means, and for outputting the difference.

5. The resistance-to-digital converter according to claim 1, further comprising a clock oscillator that has a same configuration as said CR oscillator, and that supplies its oscillation output to said time period counting means as a clock signal to be counted.

6. The resistance-to-digital converter according to claim 5, further comprising, on a chip including said clock oscillator, an external terminal for connecting at least one of a resistance and a capacitance that determine its oscillation frequency.

7. The resistance-to-digital converter according to claim 1, wherein said oscillator consists of a ring oscillator delay circuit.

8. The resistance-to-digital converter according to claim 7, wherein said ring oscillator delay circuit oscillates in one of a first condition and a second condition, said ring oscillator delay circuit oscillating in the first condition at an oscillation period including the delay corresponding to the target resistor to be converted which is connected to said ring oscillator delay circuit, and oscillating in the second condition in which an input and output of said ring oscillator delay circuit are short-circuited, said resistance-to-digital converter further comprising:
target data storing means for storing the count value of said oscillation output counting means corresponding to the target resistor to be converted; and
reference data storing means for storing the count value of said oscillation output counting means during the second condition in which the input and output of said ring oscillator delay circuit are short-circuited.

9. The resistance-to-digital converter according to claim 8, further comprising difference output means for calculating a difference between the count value stored in said target data storing means and the count value stored in said reference data storing means, and for outputting the difference.

10. The resistance-to-digital converter according to claim 9, further comprising a clock delay circuit that has a same configuration as said ring oscillator delay circuit, and that supplies its oscillation output to said time period counting means as its clock signal.

11. The resistance-to-digital converter according to claim 10, further comprising, on a chip including said clock delay circuit, an external terminal for connecting a resistance that determines the delay of said clock delay circuit.

12. The resistance-to-digital converter according to claim 1, further comprising overflow check means for checking whether said oscillation output counting means overflows or not while counting the oscillation output.

13. The resistance-to-digital converter according to claim 1, further comprising count value setting means for setting a desired value to said oscillation output counting means.

14. The resistance-to-digital converter according to claim 1, further comprising count value setting means for setting a desired value to said time period counting means.
